(19) United States
(12) Patent Application Publication
(10) Pub. No.: US 2026/0333591 A1
(43) Pub. Date: Oct. 22, 2026

(54) FLEXIBLE ELECTRIC ELEMENTS AND METHODS OF PRODUCING A FLEXIBLE ELECTRIC ELEMENT

(71) Applicant: LOOMIA Technologies, Inc., Brooklyn, NY (US)

(72) Inventors: Ezgi UCAR, Brooklyn, NY (US); Madison Thea MAXEY, San Diego, CA (US); Hannah KIM, Laurel, MD (US); Ginette LU, Glenmont, NY (US); Kevin A. DAVIS, North Andover, MA (US)

(73) Assignee: LOOMIA Technologies, Inc., Brooklyn, NY (US)

(21) Appl. No.: 19/158,368

(22) PCT Filed: Feb. 20, 2024
(86) PCT No.: PCT/US2024/016515

§ 371 Date: Aug. 20, 2025

Related U.S. Application Data
(60) Provisional application No. 63/486,108, filed on Feb. 21, 2023.
(60) Provisional application No. 63/486,134, filed on Feb. 21, 2023.

(51) Int. Cl. H05K 3/46; H05K 1/02; H05K 1/03; H05K 1/185; H05K 1/189; H05K 3/10; H05K 3/303; H05K 3/321; H05K 3/38

(52) U.S. Cl. CPC H05K 3/4673; H05K 1/0212; H05K 1/0283; H05K 1/0346; H05K 1/186; H05K 1/189; H05K 3/103; H05K 3/305; H05K 3/321; H05K 3/386; H05K 3/4697; H05K 2201/09263; H05K 2201/10196; H05K 2203/1115

(57) ABSTRACT

Disclosed is a method for fabricating a flexible circuit, the method including: applying a first adhesive in a shape of a circuit geometry onto a first insulating layer; applying a first conductive sheet onto the first insulating layer; bonding a circuit portion of the first conductive sheet to the first adhesive, wherein the circuit portion of the first conductive sheet is in the shape of the circuit geometry; attaching one or more electronic components to the circuit portion of the first conductive sheet; and applying a second insulating layer onto the first insulating layer, such that the circuit portion of the first conductive sheet is disposed between the first insulating layer and the second insulating layer.

### CROSS-REFERENCE TO RELATED APPLICATIONS

This application is the U.S. national phase entry under 35 U.S.C. § 371 of, and claims priority to, International Application No. PCT/US2024/016515, filed Feb. 20, 2024, which patent application claims the benefit under 35 U.S.C. § 119 to U.S. Provisional Patent Application No. 63/486,108, filed on Feb. 21, 2023 and to U.S. Provisional Patent Application No. 63/486,134, filed on Feb. 21, 2023, the entireties of which are incorporated herein by reference.

### TECHNICAL FIELD

The present disclosure relates generally to the field of flexible electronics elements for articles, such as textile articles.

### BACKGROUND

Manufacturable electronic or circuit systems consist largely of rigid circuits or flexible electric elements that are limited in their flexibility, largely flexing in just one direction and having significant bend-radius limitations. Soft, flexible electric elements are desirable for a range of applications in which electronics integrate with textiles. These applications may be, for example, in the medical field, in wearable technology, in automotive steering wheels and interiors and more.

### SUMMARY

In some aspects, the techniques described herein relate to a method for fabricating a flexible circuit, the method including: applying a first adhesive in a shape of a circuit geometry onto a first insulating layer; applying a first conductive sheet onto the first insulating layer; bonding a circuit portion of the first conductive sheet to the first adhesive, wherein the circuit portion of the first conductive sheet is in the shape of the circuit geometry; attaching one or more electronic components to the circuit portion of the first conductive sheet; and applying a second insulating layer onto the first insulating layer, such that the circuit portion of the first conductive sheet is disposed between the first insulating layer and the second insulating layer.

In some aspects, the techniques described herein relate to a method for fabricating a flexible heating element, the method including: applying a first adhesive in a shape of a circuit geometry onto a first insulating layer; applying a first conductive sheet onto the first insulating layer; bonding a circuit portion of the first conductive sheet to the first adhesive, wherein the circuit portion of the first conductive sheet is in the shape of the circuit geometry; attaching one or more piezoresistive components to the circuit portion of the first conductive sheet; applying a second insulating layer onto the first insulating layer, such that the circuit portion of the first conductive sheet is disposed between the first insulating layer and the second insulating layer; and connecting the circuit portion to a controller

In some aspects, the techniques described herein relate to a flexible circuit including: a first insulating layer; a first circuit portion bonded to the first insulating layer in the shape of a first circuit geometry; one or more first electronic components bonded to the first circuit portion; and a second insulating layer bonded to the first insulating layer, the second insulating layer including vacancies to accommodate one or more of the first electronic components, wherein the first circuit portion is disposed between the first insulating layer and the second insulating layer.

It is to be understood that both the foregoing general description and the following detailed description are exemplary and explanatory only and are not restrictive of the detailed embodiments, as claimed.

### BRIEF DESCRIPTION OF THE DRAWINGS

The accompanying drawings, which are incorporated in and constitute a part of this specification, illustrate exemplary embodiments of the present disclosure and together with the description, serve to explain the principles of the disclosure.

FIG. 1 is a schematic diagram depicting an exploded view of aspects of an exemplary method of producing a flexible electric element, according to one or more embodiments.

FIG. 2A depicts a top view of an exemplary flexible electric element, according to one or more embodiments.

FIG. 2B depicts a cross-sectional view of the exemplary flexible electric element of FIG. 2A taken along line 2B.

FIG. 3 is a schematic diagram depicting an exploded view of aspects of an exemplary method of producing a flexible electric element, according to one or more embodiments.

FIG. 4A depicts a top view of an exemplary flexible electric element, according to one or more embodiments.

FIG. 4B depicts a cross-sectional view of the exemplary flexible electric element of FIG. 4A taken along line 4B.

FIG. 5 depicts a schematic diagram of an exemplary circuit geometry, according to one or more embodiments.

FIG. 6 depicts a schematic diagram of an exemplary circuit geometry, according to one or more embodiments.

FIG. 7 depicts a schematic diagram of an exemplary circuit geometry, according to one or more embodiments.

FIG. 8 depicts an exemplary flexible electric element bonded to a fabric, according to one or more embodiments.

### DETAILED DESCRIPTION

While principles of the present disclosure are described herein with reference to illustrative embodiments for particular applications, it should be understood that the disclosure is not limited thereto. Those having ordinary skill in the art and access to the teachings provided herein will recognize additional modifications, applications, embodiments, and substitution of equivalents all fall within the scope of the embodiments described herein. Accordingly, the invention is not to be considered as limited by the foregoing description.

Various non-limiting embodiments of the present disclosure will now be described to provide an overall understanding of the principles of the methods described herein for producing flexible, drapable electronic circuitry layers. The technology disclosed herein, in one example, is a flexible, drapable electronic circuitry layer that may be readily integrated into, for example, textiles, foams, fabrics, leather, etc. In an exemplary embodiment, disclosed is a scalable method of making a soft, flexible, drapable flexible electric element that may be comprised of one layer or many layers. The flexible electric element may be designed so that it is modular and readily includes and incorporates a variety of electronic components, such as but not limited to, light-emitting diodes (LEDs), printed circuit boards (PCBs), thermistors, capacitors, etc. In some embodiments, the flexible electric element may comprise a heating element, and the heating element may be textile-based and encapsulated using a polymer material so that the heating element may be disposed comfortably within a textile, foam, fabric, leather, etc.

The technology disclosed herein may have several industrial applications. For example, the system may be used by medical workers, construction workers, cold-weather athletes, elderly persons, handicapped persons, or any other suitable person. It may also be used for non-apparel applications such as automotive interiors or heated warm supply-chain bags. In the exemplary embodiment, the system may include functionality for controlling a function of the flexible electric element, e.g., a temperature of a textile-based heating element with a temperature sensor (e.g., a thermistor or any other suitable sensor). The system may be powered using a battery or batteries, e.g., a rechargeable battery. In some examples, the rechargeable battery may be a Nickel-metal hydride battery (NiMH). The battery may be integrated into the flexible electric element, and may be charged using an induction charging circuit or a contact charge connector. The flexible electric element may be waterproof for safety or the electronics may be insulated

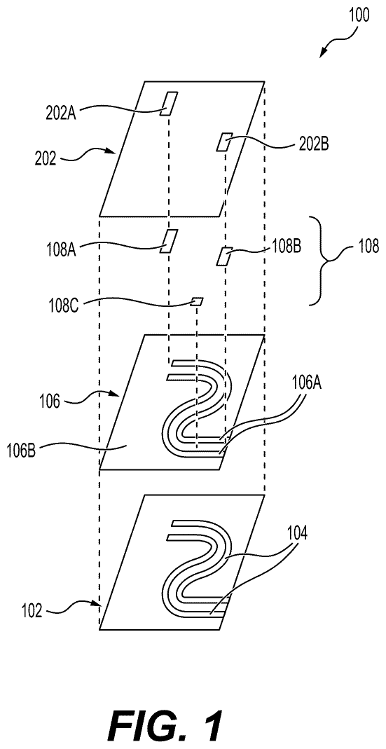

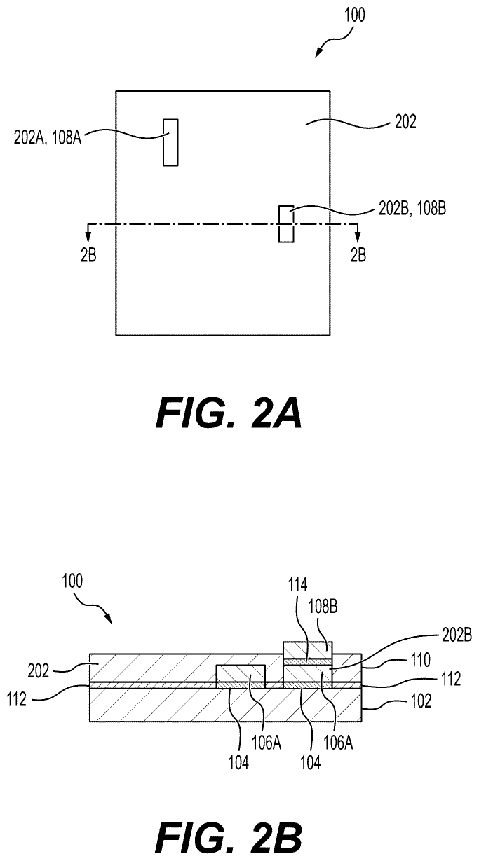

With reference to FIGS. 1-2B, an exemplary single layer flexible, drapable flexible electric element and method of fabrication will be described. FIG. 1 is a schematic diagram depicting an exploded view of aspects of an exemplary method of producing a single layer flexible electric element. The method of fabricating the single layer flexible, drapable flexible electric element 100 may begin with the provision of a first insulating layer 102. The first insulating layer 102 may be comprised of thermoplastic polyurethane (TPU) or any other polymeric film of similar chemistry. The first insulating layer 102 may include a lining adhesive for adhering to other TPU films.

There may also be provided a liner for stability within the production process. The first insulating layer 102 may be kept on the liner until the final phase of production to keep floppy materials stable throughout the production process. The first insulating layer 102 may be opaque or translucent.

A first adhesive 104 may be applied to the first insulating layer 102 in the shape of a desired circuit geometry, e.g., a series of substantially serpentine S-shaped configurations as shown in FIG. 1. The first adhesive 104 may be screen printed onto the first insulating layer 102. A first conductive sheet 106 may be applied onto the first insulating layer 102, with the first adhesive 104 disposed between the first insulating layer 102 and the first conductive sheet 106.

The first conductive sheet 106 may be a sheet of conductive textile or conductive fabric. The first conductive sheet is comprised of a first portion 106A that is in contact with the adhesive 104 that was applied to the first insulating layer, and a second portion 106B that is not in contact with the adhesive 104. The first adhesive 104 may be an ultraviolet or air-cure adhesive, and bonding the first portion 106A to the first insulating layer 102 may be achieved by curing the first adhesive 104 with ultraviolet radiation or exposure to another curing agent. The bonding may be performed with another method that will not activate the film. The first portion 106A is thus bonded to the first insulating layer in the shape of a circuit geometry. After the first portion 106A is bonded to the first insulating layer 102 via adhesive 104, the second portion 106B may be cut away using, for example, a die-cut or kiss-cut process. The second portion 106B is excess and is removed from and does not form a part of fabricated flexible electric element 100.

One or more electronic components 108 may be attached to the first portion 106A of the first conductive sheet 106, the first portion 106A forming a circuit portion in the shape of the circuit geometry. The electronic components may be attached using an epoxy. Some components may be attached using a conductive epoxy while others may be attached using a non-conductive epoxy. The electronic components 108 may include, for example, a set of connector pins 108A, an LED 108B, and a peizoresistive element 108C. These components are only provided as an example and it would be apparent to one having ordinary skill in the art that other electronic components 108 may be applied with predictable results.

A second insulating layer 202 may be applied onto the first insulating layer 102, with the first conductive portion 106A disposed between the first insulating layer 102 and the second insulating layer 202. The second insulating layer 202 may include vacancies, such as vacancy 202A and vacancy 202B, to accommodate one or more of the electronic components 108. Not all electronic components 108 necessitate a vacancy. For example, in the example shown in FIG. 1, no vacancy is provided for piezoresistive element 108C. The determination of including a vacancy for an electronic component 108 may be made based on the need for a user to see and/or directly touch the electronic component in a final assembly.

The second insulating layer 202 may be bonded to the first insulating layer 102 via bonding layer 112 (see FIG. 2B). This may be achieved by bonding the second insulating layer 202 to a lining adhesive if the first insulating layer 102 includes a lining adhesive. In such examples, the lining adhesive forms the bonding layer 112. In other examples, the second insulating layer 202 may be a dielectric insulating layer that is heat-sealed to the first insulating layer 102. In such examples, the bonding layer 112 is a representation of the bonding between the first insulating layer 102 and the second insulating layer 202.

FIGS. 2A and 2B depict a top view and a cross-sectional view of the exemplary single-layer flexible electric element 100 described by the fabrication process depicted in FIG. 1, respectively. The single-layer flexible electric element 100 depicted in FIGS. 2A and 2B is the fabricated product described by the fabrication process depicted in FIG. 1. In the top view depicted in FIG. 2A, the second (top) insulating layer 202 is visible as are, through the vacancy 202A and the vacancy 202B, the electronic components 108A and 108B, respectively, which are connector pins 108A and an LED 108B in the example shown. The remaining layers are obscured by the second insulating layer 202.

In the cross-sectional view of FIG. 2B, the layered construction of the single-layer flexible electric element 100 is depicted as described by the fabrication process in FIG. 1. The first insulating layer 102 forms a bottom layer for the element 100. A bonding layer follows, with bonding layer 112 to bond the first insulating layer 102 to the second insulating layer 202, and an adhesive 104 to bond the first insulating layer 102 to the circuit portion 106A. Note that second portion 106B of conductive sheet 106 is not a part of the final flexible electric element 100 as it was cut away in the process described in FIG. 1. The electronic components 108 are then applied using an epoxy (not shown) onto the circuit portion 106A. LED 108B is applied onto the circuit portion. The completed circuit may terminate with exposed conductive fabric pads, wires, a printed circuit board (PCB), or standard connectors, e.g., a JST or magnetic pogo pin connector. In addition, the complete circuit may have a snap, grommet or other mechanical metal fastener integrated The cross-sectional dimensions are not to scale and are used for example purposes only as a diagrammatic tool.

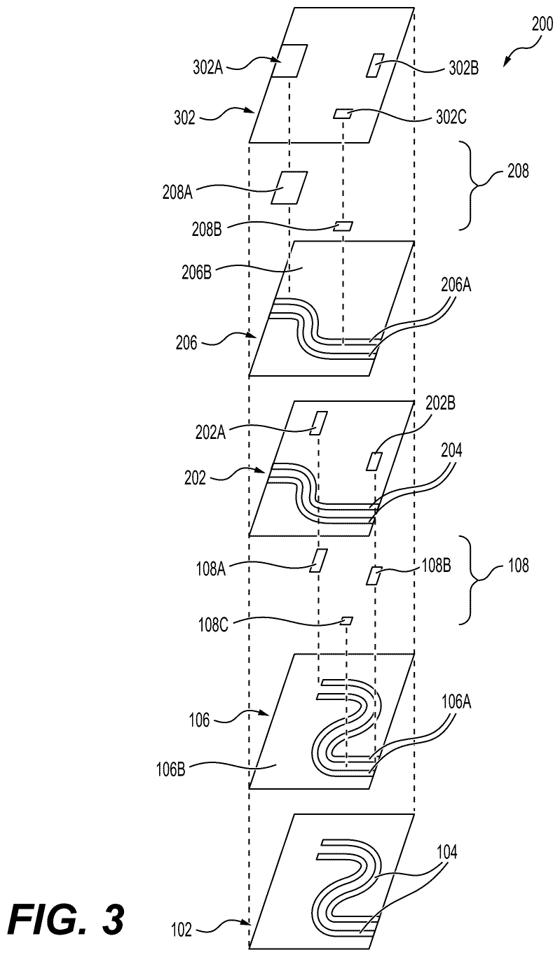

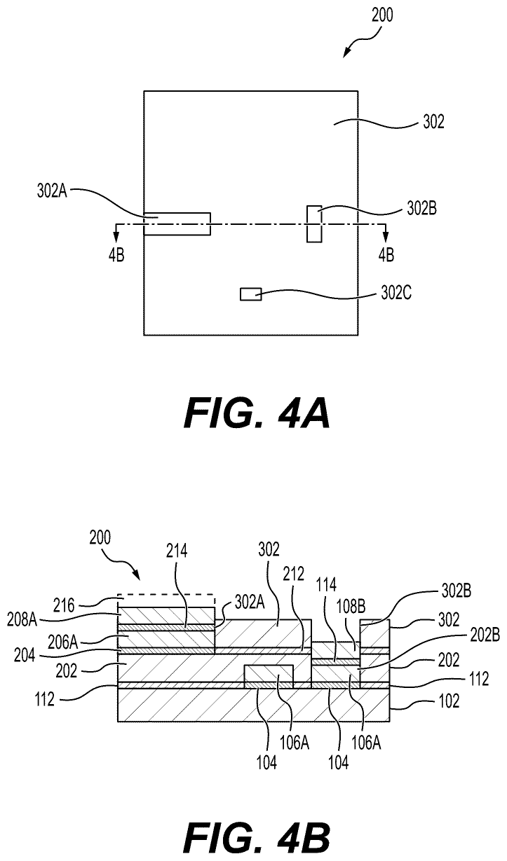

With reference to FIGS. 3-4B, an exemplary multi-layer flexible, drapable electronic element 200 and method of fabrication will be described. FIG. 3 is a schematic diagram depicting an exploded view of aspects of an exemplary method of producing a multi-layer flexible electric element. The method of fabricating the multi-layer flexible, drapable electronic element 200 may begin, similarly to the single layer electronic element 100, with the provision of a first insulating layer 102. The first insulating layer 102 may be comprised of thermoplastic polyurethane (TPU) or any other polymeric film of similar chemistry. The first insulating layer 102 may include a lining adhesive for adhering to other TPU films.

A first adhesive 104 may be applied to the first insulating layer 102 in the shape of a first desired circuit geometry, e.g., a series of substantially serpentine S-shaped configurations as shown in FIG. 3. The first adhesive 104 may be screen printed onto the first insulating layer 102. A first conductive sheet 106 may be applied onto the first insulating layer 102, with the first adhesive 104 disposed between the first insulating layer 102 and the first conductive sheet 106.

The first conductive sheet 106 may be a sheet of conductive textile or conductive fabric or conductive mesh. The first conductive sheet is comprised of a first portion 106A that is in contact with the adhesive 104 that was applied to the first insulating layer, and a second portion 106B that is not in contact with the adhesive 104. The first adhesive 104 may be an ultraviolet adhesive, and bonding the first portion 106A to the first insulating layer 102 may be achieved by curing the first adhesive 104 with ultraviolet radiation. The first portion 106A is thus bonded to the first insulating layer in the shape of a circuit geometry. After the first portion 106A is bonded to the first insulating layer 102 via adhesive 104, the second portion 106B may be cut away using, for example, a die-cut or kiss-cut process. The second portion 106B is excess and is removed from and does not form a part of fabricated flexible electric element 200.

One or more first electronic components 108 may be attached to the first portion 106A of the first conductive sheet 106, the first portion 106A forming a circuit portion in the shape of the circuit geometry. The first electronic components 108 may be attached using an epoxy. Some components may be attached using a conductive epoxy while others may be attached using a non-conductive epoxy. The electronic components 108 may include, for example, a set of connector pins 108A, an LED 108B, and a peizoresistive element 108C. These components are only provided as an example and it would be apparent to one having ordinary skill in the art that other electronic components 108 may be applied with predictable results.

A second insulating layer 202 may be applied onto the first insulating layer 102, with the first conductive portion 106A disposed between the first insulating layer 102 and the second insulating layer 202. The second insulating layer 202 may include vacancies, such as vacancy 202A and vacancy 202B, to accommodate one or more of the electronic components 108. Not all electronic components 108 necessitate a vacancy. For example, in the example shown in FIG. 1, no vacancy is provided for piezoresistive element 108C. The determination of including a vacancy for an electronic component 108 may be made based on the need for a user to see and/or directly touch the electronic component in a final assembly.

The second insulating layer 202 may be bonded to the first insulating layer 102 via bonding layer 112 (see FIG. 4B). This may be achieved by bonding the second insulating layer 202 to a lining adhesive if the first insulating layer 102 includes a lining adhesive. In such examples, the lining adhesive forms the bonding layer 112. In other examples, the second insulating layer 202 may be a dielectric insulating layer that is heat-sealed to the first insulating layer 102. In such examples, the bonding layer 112 is a representation of the bonding between the first insulating layer 102 and the second insulating layer 202.

A second adhesive 204 may be applied to the second insulating layer 202 in the shape of a second desired circuit geometry, e.g., a series of substantially serpentine S-shaped configurations as shown in FIG. 3 (note that the second circuit geometry need not match the first circuit geometry). The second adhesive 204 may be screen printed onto the second insulating layer 202. A second conductive sheet 206 may be applied onto the second insulating layer 202, with the second adhesive 204 disposed between the second insulating layer 202 and the second conductive sheet 206.

The second conductive sheet 206 may be a sheet of conductive textile or conductive fabric. The second conductive sheet is comprised of a first portion 206A that is in contact with the adhesive 204 that was applied to the second insulating layer, and a second portion 206B that is not in contact with the adhesive 204. The second adhesive 204 may be an ultraviolet adhesive, and bonding the first portion 206A to the second insulating layer 202 may be achieved by curing the second adhesive 204 with ultraviolet radiation. The first portion 206A is thus bonded to the second insulating layer in the shape of a second circuit geometry. After the first portion 206A is bonded to the second insulating layer 202 via adhesive 204, the second portion 206B may be cut away using, for example, a die-cut or kiss-cut process. The second portion 206B is excess and is removed from and does not form a part of fabricated flexible electric element 200.

One or more second electronic components 208 may be attached to the first portion 206A of the second conductive sheet 206, the first portion 206A forming a circuit portion in the shape of the second circuit geometry. The electronic components 208 may be attached using an epoxy. Some components may be attached using a conductive epoxy while others may be attached using a non-conductive epoxy. The electronic components 208 may include, for example, a printed circuit board 208A and a thermistor 208B. These components are only provided as an example and it would be apparent to one having ordinary skill in the art that other electronic components 108 may be applied with predictable results.

A third insulating layer 302 may be applied onto the second insulating layer 202, with the first portion 206A of conductive sheet 206 disposed between the second insulating layer 202 and the third insulating layer 302. The third insulating layer 302 may include vacancies, such as vacancy 302A, vacancy 302B, and vacancy 302C, to accommodate one or more of first electronic components 108 and/or second electronic components 208.

The third insulating layer 302 may be bonded to the second insulating layer 202 via bonding layer 212 (see FIG. 4B). This may be achieved by bonding the third insulating layer 302 to a lining adhesive if the second insulating layer 202 includes a lining adhesive. In such examples, the lining adhesive forms the bonding layer 212. In other examples, the second insulating layer 302 may be a dielectric insulating layer that is heat-sealed to the second insulating layer 202. In such examples, the bonding layer 212 is a representation of the bonding between the second insulating layer 202 and the third insulating layer 302.

FIGS. 4A and 4B depict a top view and a cross-sectional view of the exemplary multi-layer flexible electric element 200 described by the fabrication process depicted in FIG. 3, respectively. The multi-layer flexible electric element 200 depicted in FIGS. 4A and 4B is the fabricated product described by the fabrication process depicted in FIG. 3. In the top view depicted in FIG. 4A, the third (top) insulating layer 302 is visible as are, through the vacancy 302A, the vacancy 302B, and the vacancy 302C, the electronic components 208A, 108B, and 208C, respectively. The remaining layers are obscured by the third insulating layer 302.

In the cross-sectional view of FIG. 4B, the layered construction of the multi-layer flexible electronic element 200 is depicted as described by the fabrication process in FIG. 3. The first insulating layer 102 forms a bottom layer for the element 100. A bonding layer follows, with bonding layer 112 to bond the first insulating layer 102 to the second insulating layer 202, and an adhesive layer 104 to bond the first insulating layer 102 to the circuit portion 106A. Note that second portion 106B of conductive sheet 106 is not a part of the final flexible electronic element 100 as it was cut away in the process described in FIG. 1. The electronic components 108 are then applied using an epoxy (not shown) onto the circuit portion 106A. The second insulating layer 202 is bonded to the first insulating layer 102 via the bonding layer 112, with circuit portion 106A disposed between the first insulating layer 102 and the second insulating layer 202.

A bonding layer follows, with bonding layer 212 to bond the first insulating layer 202 to the third insulating layer 302, and an adhesive 204 to bond the second insulating layer 202 to the circuit portion 206A. Note that second portion 206B of conductive sheet 206 is not a part of the final flexible electronic element 200 as it was cut away in the process described in FIG. 4. The electronic components 208 are then applied using an epoxy (not shown) onto the circuit portion 206A. The second insulating layer 302 is bonded to the first insulating layer 202 via the bonding layer 212, with circuit portion 206A disposed between the second insulating layer 202 and the third insulating layer 302. An epoxy 216 may be added to coat any exposed electronic components 108 or 208.

The multi-layer electronic element 200 described in FIGS. 3-4B comprises two layers, but the process may be repeated N times, where N is a positive integer, to create an N-layered electronic element, with each Nth insulating layer forming the top of an N−1-layer electronic element.

In some embodiments, the single layer electronic element 100 described in FIGS. 1-2B or the multi-layer electronic element 200 described in FIGS. 3-4B may be or may include an electric heating element. In these embodiments, the electronic components 108 and 208 may include thermistors and piezoresistive elements. The circuit portion 106A or 206A may be connected to a controller (not shown) that modulates the circuit portion between a capacitive sensing mode and a heating mode.

In some cases, the circuit geometry itself may be programmed to alternate between providing heat and sensing for a change in the capacitive field, with a capacitor included among the electronic components 108 or 208. Unlike many capacitive sensing mechanisms that require two conductive layers separated by a dielectric, using the circuit geometry as a capacitive sensing antenna allows for a single layer to both act as a sensor and a heater.

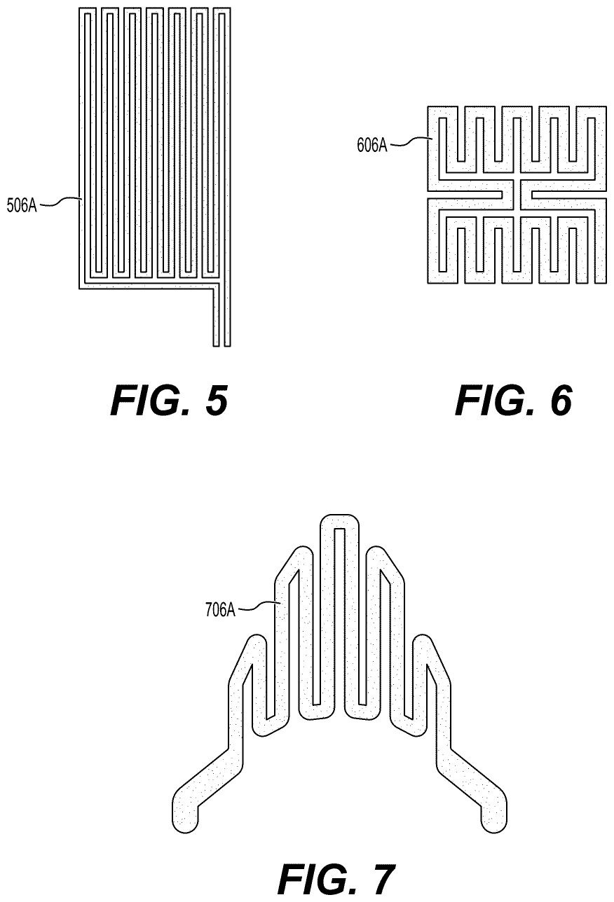

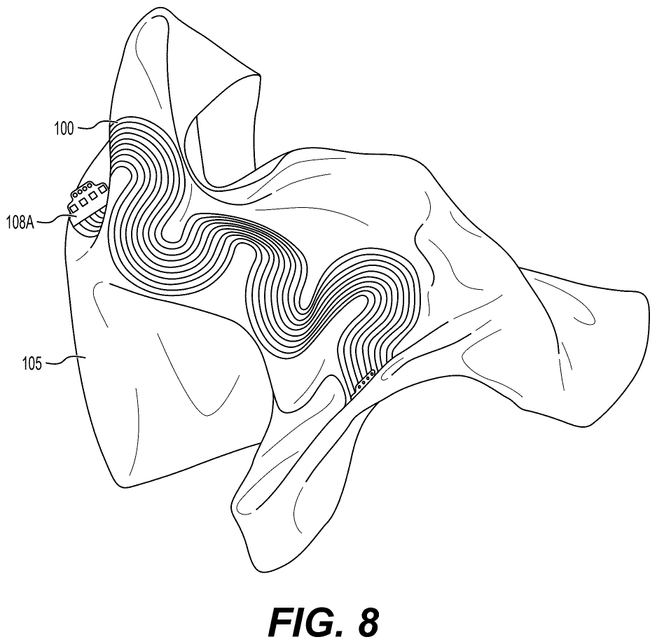

FIGS. 5-7 depict a variety of circuit geometries 506A-706A that may provide desirable qualities in flexible circuit electronics, namely providing space-filling qualities while also exhibiting desirable qualities in terms of stretch. Circuit geometry 506A depicted in FIG. 5 provides a substantially serpentine pattern that fills space and provides two-way stretch by providing traces that are generally provided in the same direction (up-down in FIG. 5). Circuit geometry 606A in FIG. 6 provides a space-filling pattern that provides four-way stretch by providing traces that are generally provided equally in two perpendicular directions (up-down and left-right in FIG. 6). Circuit geometry 706A provides an example of a free-form circuit geometry.

FIG. 8 depicts an exemplary flexible electric element 100 bonded to a fabric 105. The drapable and flexible qualities of the flexible electric element 100 may be demonstrated herein. The field of manufacturable electronic or circuit systems consists primarily of rigid circuits or flexible electric elements that largely flex in one direction and have bend-radius limitations. The disclosed soft, flexible electric elements 100, 200 are capable of flexing in multiple directions without bend-radius limitations and are useful for a range of applications where electronics must mate with textiles, such as fabric 105. These applications may be, for example, in the medical field, in wearable technology, in automotive steering wheels and interiors, etc.

The techniques disclosed herein may be used for a range of applications such as creating interconnects and heaters. The techniques may also include inserting pressure sensitive materials or spacing rings to create pressure sensors or switches. This results in a highly conductive circuit that has the drape and movement of a textile.

The conductive sheets 106, 206 may be knit or woven and may have a polymer core such as a Nylon or Polyester. This unplated fabric is then electroplated in silver, copper or a copper alloy or other metal to create a conductive surface. The conductive fabric will need to be sheeted from a roll for the techniques described herein.

If there are embedded sensors such as temperature sensors or photoresistors, the sensors may be placed directly onto the conductive sheets 106, 206 using a conductive epoxy for an electrical connection. The conductive epoxy may require a curing window to reach full hardness and conductivity. After parts are attached, an optional addition of structural epoxy may be desired to provide tension relief between the conductive fabric and the integrated component.

Sheets of force resistive material may also be applied, or layers of spacer rings before applying and additional layer of film to encapsulate the circuit. Once all layers are placed, the top adhesive or film may be placed to close that layer of the circuit. This assembly is sealed with a heat press or oven and additional layers can be applied before or after the heat curing process.

These and other embodiments of the systems and methods may be used as would be recognized by those skilled in the art. The above descriptions of various systems and methods are intended to illustrate specific examples and describe certain ways of making and using the systems disclosed and described here. These descriptions are neither intended to be nor should be taken as an exhaustive list of the possible ways in which these systems can be made and used. A number of modifications, including substitutions of systems between or among examples and variations among combinations can be made. Those modifications and variations should be apparent to those of ordinary skill in this area after having read this disclosure.

The systems, apparatuses, devices, and methods disclosed herein are described in detail by way of examples and with reference to the figures. The examples discussed herein are examples only and are provided to assist in the explanation of the apparatuses, devices, systems and methods described herein. None of the features or components shown in the drawings or discussed below should be taken as mandatory for any specific implementation of any of these the apparatuses, devices, systems or methods unless specifically designated as mandatory. For ease of reading and clarity, certain components, modules, or methods may be described solely in connection with a specific figure. In this disclosure, any identification of specific techniques, arrangements, etc. are either related to a specific example presented or are merely a general description of such a technique, arrangement, etc. Identifications of specific details or examples are not intended to be, and should not be, construed as mandatory or limiting unless specifically designated as such. Any failure to specifically describe a combination or sub-combination of components should not be understood as an indication that any combination or sub-combination is not possible. It will be appreciated that modifications to disclosed and described examples, arrangements, configurations, components, elements, apparatuses, devices, systems, methods, etc. can be made and may be desired for a specific application. Also, for any methods described, regardless of whether the method is described in conjunction with a flow diagram, it should be understood that unless otherwise specified or required by context, any explicit or implicit ordering of steps performed in the execution of a method does not imply that those steps must be performed in the order presented but instead may be performed in a different order or in parallel.

Reference throughout the specification to “various embodiments,” “some embodiments,” “one embodiment,” “some example embodiments,” “one example embodiment,” or “an embodiment” means that a particular feature, structure, or characteristic described in connection with any embodiment is included in at least one embodiment. Thus, appearances of the phrases “in various embodiments,” “in some embodiments,” “in one embodiment,” “some example embodiments,” “one example embodiment, or “in an embodiment” in places throughout the specification are not necessarily all referring to the same embodiment. Furthermore, the particular features, structures or characteristics may be combined in any suitable manner in one or more embodiments.

Throughout this disclosure, references to components or modules generally refer to items that logically can be grouped together to perform a function or group of related functions. Like reference numerals are generally intended to refer to the same or similar components. Those of ordinary skill in the art will recognize that the systems, apparatuses, devices, and methods described herein can be applied to, or easily modified for use with, other types of applications.

It is intended that the specification and examples be considered as exemplary only, with a true scope and spirit of the invention being indicated by the following claims.

What is claimed is:

1. A method for fabricating a flexible circuit, the method comprising:
applying a first adhesive in a shape of a circuit geometry onto a first insulating layer;
applying a first conductive sheet onto the first insulating layer;
bonding a circuit portion of the first conductive sheet to the first adhesive, wherein the circuit portion of the first conductive sheet is in the shape of the circuit geometry;
attaching one or more electronic components to the circuit portion of the first conductive sheet; and
applying a second insulating layer onto the first insulating layer, such that the circuit portion of the first conductive sheet is disposed between the first insulating layer and the second insulating layer.

2. The method of claim 1, wherein the first insulating layer is a thermoplastic polyurethane (TPU) layer.

3. The method of claim 1, wherein the first adhesive is an ultraviolet adhesive or air curing, and bonding the first conductive layer to the first adhesive comprises curing the adhesive with ultraviolet radiation or other curing agent.

4. The method of claim 1, wherein one or more of the electronic components are attached to the circuit portion with a conductive epoxy.

5. The method of claim 1, wherein one or more of the electronic components are attached to the circuit portion with a non-conductive epoxy.

6. The method of claim 1, wherein the second insulating layer includes vacancies to accommodate one or more of the electronic components.

7. The method of claim 1, wherein the second insulating layer is heat-sealed to the first insulating layer.

8. The method of claim 1, wherein the first insulating layer becomes adhesive with heat adhesive, and the second insulating layer is bonded to the first insulating layer when heated

9. The method of claim 1, wherein the first conductive sheet includes a bonding portion and an excess portion, the method further comprising removing the excess portion after bonding the circuit portion to the first adhesive.

10. The method of claim 1, wherein the one or more electronic components includes a piezoresistive element.

11. The method of claim 1, further comprising applying an insulating epoxy to one or more of the electronic components.

12. The method of claim 1, further comprising connecting the circuit portion to a controller that modulates the circuit portion between a capacitive sensing mode and a heating mode.

13. The method of claim 1, further comprising:
applying a third adhesive in a shape of a second circuit geometry onto the second insulating layer;
applying a second conductive sheet onto the second insulating layer;
bonding a circuit portion of the second conductive sheet to the third adhesive, wherein the circuit portion of the second conductive sheet is in the shape of the second circuit geometry;
attaching one or more electronic components to the circuit portion of the second conductive sheet; and
applying a third insulating layer onto the second insulating layer, such that the circuit portion of the second conductive sheet is disposed between the second insulating layer and the third insulating layer.

14. A method for fabricating a flexible heating element, the method comprising:
applying a first adhesive in a shape of a circuit geometry onto a first insulating layer;
applying a first conductive sheet onto the first insulating layer;
bonding a circuit portion of the first conductive sheet to the first adhesive, wherein the circuit portion of the first conductive sheet is in the shape of the circuit geometry;
attaching one or more piezoresistive components to the circuit portion of the first conductive sheet;
applying a second insulating layer onto the first insulating layer, such that the circuit portion of the first conductive sheet is disposed between the first insulating layer and the second insulating layer; and
connecting the circuit portion to a controller that modulates the circuit portion between a capacitive sensing mode and a heating mode.

15. The method of claim 14, wherein the first insulating layer is a thermoplastic polyurethane (TPU) layer.

16. The method of claim 14, wherein the first adhesive is an ultraviolet adhesive or air cure adhesive, and bonding the first conductive layer to the first adhesive comprises curing the adhesive with ultraviolet radiation or other curing agent.

17. The method of claim 14, wherein the shape of the circuit geometry is a substantially serpentine or space-filling shape, the substantially space-filling/serpentine shape configured to provide two-way stretch.

18. The method of claim 14, wherein the shape of the circuit geometry is a configured to provide four-way stretch.

19. A flexible circuit comprising:
a first insulating layer;
a first circuit portion bonded to the first insulating layer in a shape of a first circuit geometry;
one or more first electronic components bonded to the first circuit portion; and
a second insulating layer bonded to the first insulating layer, the second insulating layer including vacancies to accommodate one or more of the first electronic components,
wherein the first circuit portion is disposed between the first insulating layer and the second insulating layer.

20. The flexible circuit of claim 19, further comprising:
a second circuit portion bonded to the second insulating layer in a shape of a second circuit geometry;
one or more second electronic components bonded to the second circuit portion; and
a third insulating layer bonded to the second insulating layer, the third insulating layer including vacancies to accommodate one or more of the first electronic components and one or more of the second electronic components,
wherein the second circuit portion is disposed between the second insulating layer and the third insulating layer.
